(19) United States
(12) Patent Application Publication
(10) Pub. No.: US 2023/0245905 A1
(43) Pub. Date: Aug. 3, 2023

(54) MULTI-ZONE LAMINATE HEATER PLATE

(71) Applicant: ASM IP Holding B.V., Almere (NL)

(72) Inventors: Joaquin Aguilar Santillan, Gilbert, AZ (US); Shubham Garg, Tempe, AZ (US); Hong Gao, San Jose, CA (US); Todd Dunn, Cave Creek, AZ (US); Shanker Kuttath, Austin, TX (US)

(21) Appl. No.: 18/101,656

(22) Filed: Jan. 26, 2023

Related U.S. Application Data
(60) Provisional application No. 63/305,132, filed on Jan. 31, 2022.

(51) Int. Cl. H01L 21/67; H05B 3/28; G01K 1/02; B32B 18/00; B32B 3/26; B32B 3/08; H01L 21/683

(52) U.S. Cl. CPC H01L 21/67109; H05B 3/283; G01K 1/026; B32B 18/00; B32B 3/26; B32B 3/08; H01L 21/67248; H01L 21/6833; H05B 2203/005; B32B 2307/3065; B32B 2307/302

(57) ABSTRACT

A heater assembly having a laminate heater plate and a shaft. The laminate heater plate is formed from a plurality of layers, wherein one or more layers may comprise one or more of a heating element, an RF electrode, a cooling channel, and an RTD sensor.

### CROSS-REFERENCE TO RELATED APPLICATIONS

This application is a nonprovisional of, and claims priority to and the benefit of, U.S. Provisional Patent Application No. 63/305,132, filed Jan. 31, 2022 and entitled “LAMINATE HEATER PLATE,” which is hereby incorporated by reference herein.

### FIELD OF INVENTION

The present disclosure generally relates to a laminate heater plate. More particularly, the present disclosure relates to a laminate heater plate with and integrated RF electrode, RTD sensors, heating elements, and channels.

### BACKGROUND OF THE DISCLOSURE

Equipment used during the semiconductor manufacturing process may provide a susceptor (i.e., a heater plate) to support the substrate (e.g., a wafer). In some cases, the heater plate also provides an electrostatic chucking (ESC) function. Conventional ESC susceptors may not provide the desired temperature control.

### SUMMARY OF THE INVENTION

A heater assembly having a laminate heater plate and a shaft. The laminate heater plate is formed from a plurality of layers, wherein one or more layers may comprise one or more of a heating element, an RF electrode, a cooling channel, and an RTD sensor.

According to one aspect, a substrate support assembly, comprises: a laminate heater plate comprising: a plurality of layers comprising: a first layer comprising an RF electrode; a second layer comprising a first resistance temperature detector (RTD); and a third layer comprising a heating element; wherein the first, second, and third layers are arranged horizontally and stacked; and a first channel extending vertically through the plurality of layers; a shaft coupled to the laminate heater plate and comprising: a hollow center defined by a sidewall; and a second channel disposed within the sidewall and fluidly connected to the first channel.

In the above substrate support assembly, each layer from the plurality of layers is formed from a ceramic material comprising aluminum nitride (AlN), aluminum oxide (Al₂O₃), or dialuminium magnesium tetraoxide (Al₂MgO₄).

In the above substrate support assembly, wherein the second layer comprises a first plurality of RTDs forming concentric circles.

In the above substrate support assembly, wherein the third layer comprises a plurality of heating elements comprising a first heating element, a second heating element, and a third heating element.

In the above substrate support assembly, the first heating element is disposed a first distance from a center point of the laminate heater plate, the second heating element is disposed a second distance from the center point of the laminate heater plate, and the third heating element is disposed a third distance from the center point of the laminate heater plate, wherein the second distance is greater than the first distance, and the third distance is greater than the second distance.

In the above substrate support assembly, the first, second, and third heating elements are electrically isolated from each other.

In the above substrate support assembly, the second layer is disposed between the first layer and the third layer.

In the above substrate support assembly, the substrate support assembly further comprises a fourth layer comprising a second plurality of RTDs.

In the above substrate support assembly, the fourth layer is disposed between the second layer and the third layer.

According to another aspect, a laminate heater plate comprises a plurality of layers comprising: a first layer comprising an outward facing, top surface; a second layer comprising an electrode; a third layer comprising a first plurality of resistance temperature detector (RTD); a fourth layer comprising a second plurality of RTDs; and a fifth layer comprising a plurality of heating elements, the plurality of heating elements comprising a first set of heating elements disposed within a first zone, a second set of heating elements disposed within a second zone, and a third set of heating elements disposed within a third zone, wherein the first, second, and third zones are concentric with a center point of the heater plate; wherein the first, second, third, fourth and fifth layers are arranged horizontally and stacked and in sequence.

In the above laminate heater plate, the laminate heater plate further comprises a contact area support protruding from the top surface.

In the above laminate heater plate, the laminate heater plate further comprises a first channel extending vertically from the top surface through at least the second layer.

In the above laminate heater plate, the first set of heating elements, the second set of heating elements, and the third set of heating elements are electrically isolated from each other.

In the above laminate heater plate, the laminate heater plate further comprises a sixth layer interposed between the second layer and the fifth layer.

In the above laminate heater plate, the laminate heater plate further comprises a second channel in fluid communication with the first channel and extending horizontally through the sixth layer.

In the above laminate heater plate, second layer further comprises a first ceramic material comprising one of aluminum nitride (AlN), aluminum oxide (Al₂O₃), or dialuminium magnesium tetraoxide (Al₂MgO₄); the third layer further comprises a second ceramic material that is different from the first ceramic material, the second ceramic material comprising one of aluminum nitride (AlN), aluminum oxide (Al₂O₃), or dialuminium magnesium tetraoxide (Al₂MgO₄) and the fifth layer further comprises a third ceramic material that is different from the first and second ceramic materials, the third ceramic material comprising one of aluminum nitride (AlN), aluminum oxide (Al₂O₃), or dialuminium magnesium tetraoxide (Al₂MgO₄).

In the above laminate heater plate, each layer from the plurality of layers further comprises a same ceramic material comprising one of aluminum nitride (AlN), aluminum oxide (Al₂O₃), or dialuminium magnesium tetraoxide (Al₂MgO₄).

According to another aspect, a substrate support assembly comprises: a laminate heater plate, comprising: a plurality of layers formed from a ceramic material, the plurality of layers comprising: a first layer comprising an outward facing, top surface; a second layer comprising an electrode; a third layer comprising a first plurality of resistance temperature detector (RTD); a fourth layer comprising a second plurality of RTDs; and a fifth layer comprising a plurality of heating elements, the plurality of heating elements comprising a first set of heating elements, a second set of heating elements, and a third set of heating elements; a first channel extending vertically from the top surface and through at least one layer from the plurality of layers; and a second channel extending horizontally through a sixth layer; a shaft coupled to the laminate heater plate and comprising: a hollow center defined by a sidewall; and a third channel disposed within the sidewall.

In the above substrate support assembly, the ceramic material comprises at least one of ceramic material comprising one of aluminum nitride (AlN), aluminum oxide (Al₂O₃), and dialuminium magnesium tetraoxide (Al₂MgO₄).

In the above substrate support assembly, the first set of heating elements is arranged within a first zone, the second set of heating elements is arranged in a second zone, and the third set of heating elements is arranged in a third zone, wherein the first, second, and third zones are concentric with a center point of the laminate heater plate, and wherein each set of heating elements is electrically isolated from the other sets of heating elements.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 representatively illustrates a system in accordance with various embodiments of the present technology;

FIG. 2 representatively illustrates a cross sectional view of a laminate heater plate in accordance with an embodiment of the present technology;

FIG. 3 representatively illustrates a top view of the laminate heater plate in accordance with various embodiments of the present technology;

FIG. 4 representatively illustrates a cross sectional view of a portion of the laminate heater plate in accordance with an embodiment of the present technology;

FIG. 5 representatively illustrates a cross sectional view A-A of the laminate heater plate of FIG. 3 in accordance with various embodiments of the present technology;

FIG. 6 representatively illustrates an exploded view of layers of the laminate heater plate in accordance with various embodiments of present technology; and

FIG. 7 representatively illustrates a cross sectional view of the laminate heater plate in accordance with various embodiments of the present technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

The present disclosure generally relates to a laminate heater plate used during the fabrication of semiconductor devices.

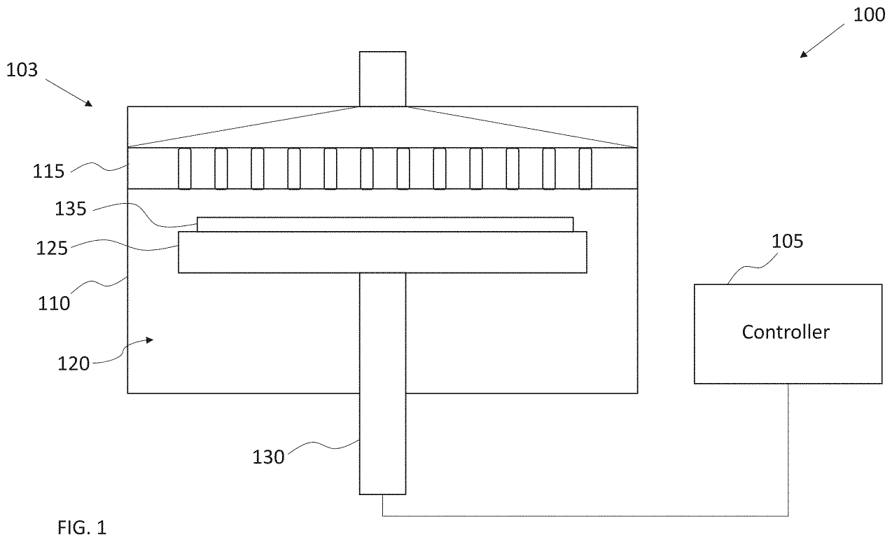

Referring to FIG. 1, an exemplary system 100 may comprise a reactor 103 electrically coupled to a controller 105. In various embodiments, the reactor 103 may comprise a reaction chamber 110 and gas distribution assembly 115. The gas distribution assembly 115 may comprise a plate comprising a plurality of holes. The gas distribution assembly 115 may be positioned above the reaction chamber 110. In various embodiments, the reaction chamber 110 may comprise a reaction space 120 defined by sidewalls of the reaction chamber 110 and the gas distribution assembly 115. The system 100 may further comprise a substrate support assembly (i.e., a heater assembly) disposed within the reaction space 120 of the reaction chamber 110 and below the gas distribution assembly 115. The substrate support assembly may be configured to support a substrate, such as a wafer 135.

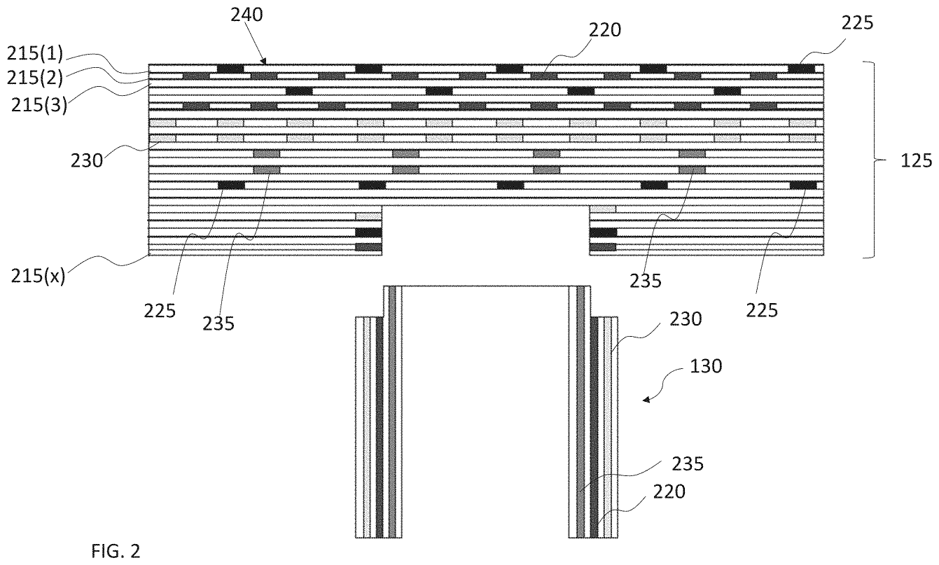

In various embodiments, and referring to FIGS. 1, 2, and 6, the substrate support assembly may comprise a heater plate 125 and a shaft 130. The shaft 130 may be physically connected to a bottom surface of the heater plate 125. The shaft 130 may comprise a hollow center defined by sidewalls of the shaft 130. FIG. 2 illustrates the heater plate 125 separated from the shaft 130, however, when fully assembled, the shaft 130 is abutting the bottom side of the heater plate 125. The heater plate 125 may have a diameter in the range of 12 inches to 18 inches and may be selected to accommodate a particular size wafer 135.

In various embodiments, the heater plate 125 may be formed from a plurality of layers 215 that are arranged horizontally, stacked together and then bonded together to form a laminated structure (i.e., a laminate heater plate). The layers 215 may be bonded together by exposing the plurality of layers to a high temperature, for example in the range of 1400° C. to 1600° C. for a number of hours (e.g., about 5 hours). The heater plate 125 may comprise any number of layers. The number of layers 215 may be based on the application of the heater plate 125, desired electrostatic clamping function, desired cooling function, desired temperature sensing function, desired overall thickness of the heater plate, and the like. Each layer 215 may have a thickness in the range of 0.3 mm to 0.99 mm. Each layer 215 may comprise a ceramic material, such as one or more of alumina, magnesium, silica, molybdenum, titanium, and/or oxygen. In particular, each layer 215 may be formed from aluminum nitride (AlN), aluminum oxide (Al₂O₃), or dialuminium magnesium tetraoxide (Al₂MgO₄). Each layer 215 may be formed using conventional methods, which may include wet grinding, dehydrating, adding solvents to create a fluid slurry, deaeration of the alumina slurry, or pouring the alumina slurry into a flat plate and cooled slowly.

In some embodiments, each layer 215 used to form the laminate heater plate 125 may be formed from the same material. For example, a laminate heater plate 125 may be formed from only layers 215 made of aluminum nitride.

Alternatively, the laminate heater plate 125 may be formed from layers made with different materials. For example, one layer may be made of aluminum nitride, while another layer in the same stack may be made of aluminum oxide, and yet another layer in the same stack may be made of dialuminium magnesium tetraoxide.

In various embodiments, each layer 215 may further comprise one or more of an RF electrode 220, a resistance temperature detector (RTD) sensor 225, a heating element 230, and a channel 235.

In various embodiments, the RF electrode 220 may be configured to provide electrostatic chucking to clamp a substrate (e.g., a wafer) to a top surface 240 of the heater plate 125. The RF electrode 220 may form a mesh pattern, a serpentine pattern, or any other suitable pattern that provides a uniform clamping force across the area of the wafer. The RF electrode 220 may comprise a metal, such molybdenum, tungsten, niobium, and/or a combination thereof. In various embodiments, the RF electrode 220 may be integrated or otherwise embedded within one or more layers of the laminate heater plate 125. In an exemplary embodiment, the RF electrode 220 may be positioned near or at the top surface of the heater plate 125. In other words, the RF electrode 125 may be integrated within one or more of the top layers (e.g., within the top 15 layers) of the laminate heater plate 125.

In various embodiments, the heater plate comprises a plurality of the RTD sensors 225, wherein each sensor 225 may be configured to sense or otherwise detect temperature. The RTD sensors 225 may be integrated or otherwise embedded within one or more layers of the heater plate 125. For example, a single layer 215 of the laminate heater plate 125 may comprise a plurality of RTD sensors 225. Additionally, or alternatively, each layer may comprise a single RTD sensor 225. Each RTD may comprise a metal wire formed from platinum, nickel, copper, or a combination thereof. In various embodiments, one or more RTD sensors 225 may be integrated within the top layer, middle layers, and/or bottom layers of the heater plate 125. The particular placement/position of the RTD sensor 225 within the overall laminate heater plate 125 may be determined according to the placement of other components, such as the RF electrode 220, the channel 235, heating elements 230, and/or any other areas where more precise temperature monitoring may be desired. In an exemplary embodiment, the RTD sensors 225 may be arranged near the channels 235, above and/or below the RF electrode 220, and/or above and/or below the heating elements 230. In addition, one or more RTD sensors 225 may be located adjacent to the shaft 130.

In various embodiments, the RTD sensors 225 arranged within one layer may have a uniform pattern, such as with equidistant spacing or other symmetric pattern. In other layers, however, the RTD sensors 225 may have a non-uniform pattern/spacing. Each RTD sensor 225 may comprise a metal, such as platinum, nickel, copper, alloys, and/or any other suitable metal.

In various embodiments, the heater plate 125 may further comprise a plurality of heating elements 230 to heat the heater plate 125 to a desired temperature. The heating elements 230 may be integrated or otherwise embedded within one or more layers of the laminate heater plate 125. The heating elements 230 may be arranged to provide a uniform heat distribution to the heater plate 125 and, as such, may be arranged in any suitable pattern, such as a serpentine pattern, a symmetric pattern, or the like. In some embodiments, the heating elements 230 may be spaced equidistant from each other and radiate outwards. For example, one heating element may be disposed a first distance from the center point, a second heating element may be disposed a second distance, farther than the first distance, from the center point, and a third heating element may be disposed a third distance, farther than the second distance, from the center point of the heating plate 125. The heating elements 230 may comprise any suitable metal, such as molybdenum, tungsten, niobium, and/or a combination thereof.

In various embodiments, the heater plate may further comprise one or more channels 235 to control the temperature of the heater plate 125. The channels 235 may be configured to flow water or other cooling fluid, or an inert gas (such as helium, argon or nitrogen) therethrough. The channels 235 may provide improved thermal uniformity to heater plate 125 and the wafer 135. In addition, in some cases, a gas may be flowed through the channel 235 to provide purging on the backside of the wafer 135.

In one embodiment, and referring to FIG. 2, the channels 235 may be embedded within the heater plate 125 and a sidewall of the shaft 130.

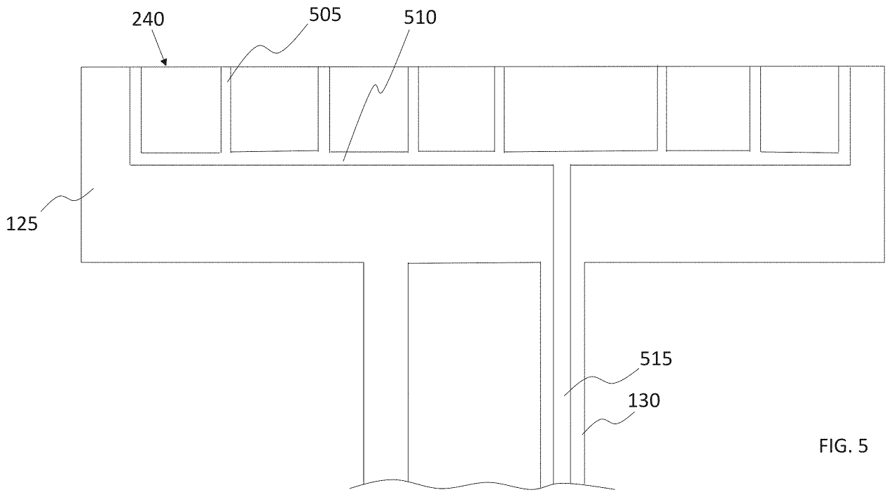

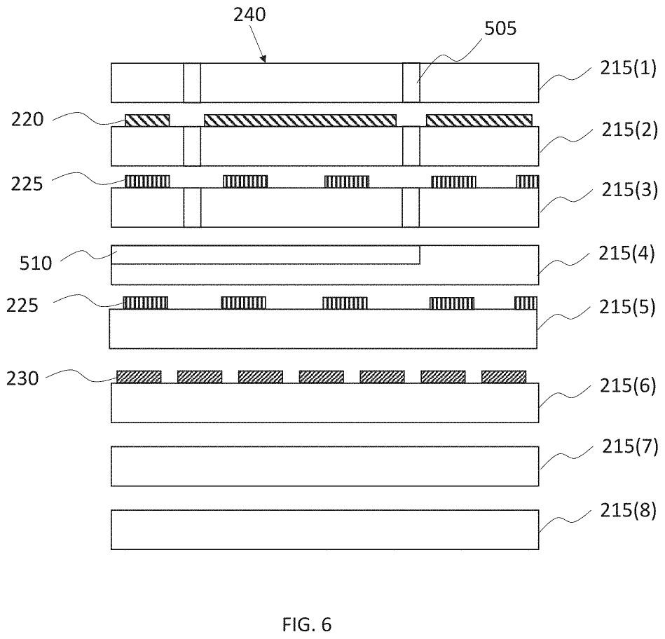

In another embodiment, and referring to FIGS. 5 and 6, the substrate support assembly may comprise a first channel 505 that is arranged vertically and extends from the top surface 240 of the heater plate 125 through a plurality of layers 215, such a first, second, and third layer 215(1)-215(3). The substrate support assembly may further comprise a second channel 510 that is arranged horizontally and is fluidly connected to the first channel 505. In addition, the substrate support assembly may further comprise a third channel 515 that is fluidly connected to the second channel 510 and extends through the sidewall of the shaft 130.

According to an exemplary embodiment, and referring to FIG. 6, a second layer 215(2) may comprise the RF electrode 220, a third layer 215(3) may comprise a first plurality of RTD sensors 225, a fourth layer 215(4) may comprise a second channel 510 oriented horizontally, a fifth layer 215(5) may comprise a second plurality of RTD sensors 225, and a sixth layer 215(6) may comprise a plurality of heating elements 230. Subsequent layers, such as layers 215(7) and 215(8) may be used for trace routing or other electrical connections.

In various embodiments, one layer 215 may contain a single element. For example, and referring to FIG. 2, the first layer 215(1) contains only RTD sensors 225, the second layer 215(2) contains only the RF electrode 220, and another layer contains only heating elements 230.

In various embodiments, and referring to FIGS. 1 and 2, the RF electrodes 220, RTD sensors 225, and heating elements 230 may be connected to the controller 105 or other processing device. The controller/processing device 105 may receive and/or send control signals to the RF electrodes 225 and the heating elements 230.

In addition, the controller/processing device 105 may be configured to measure the resistance of each RTD sensor 225 and convert the measured resistance value into a temperature. The controller/processing device 105 may use the measured resistance value and/or temperature information to control the heating elements and/or the channels. For example, if the temperature that is detected near the channel 235 is greater than desired, the controller/processing device 105 may increase the temperature of the heating elements 230 and/or decrease the cooling capability of the channels 235. Alternatively, if the temperature that is detected near the channel 235 is less than desired, the controller/processing device 105 may decrease the temperature of the heating elements 230 and/or increase the cooling capability of the channels 235.

Similarly, if the temperature that is detected near the heating element 230 is greater than desired, the controller/processing device 105 may decrease the temperature of the heating elements 230 and/or increase the cooling capability of the channels 235. Alternatively, if the temperature that is detected near the heating element 230 is less than desired, the controller/processing device 105 may increase the temperature of the heating elements 230 and/or decrease the cooling capability of the channels 235.

In addition, RTDs may be placed near or at the first layer 215(1) to measure the temperature at the top surface 240 of the laminate heater plate 125. If the temperature that is detected near the top surface 240 is greater than desired, the controller/processing device 105 may decrease the temperature of the heating elements 230 and/or increase the cooling capability of the channels 235. Alternatively, if the temperature that is detected near the top surface 240 is less than desired, the controller/processing device 105 may increase the temperature of the heating elements 230.

In various embodiments, the controller/processing device may monitor the resistance of each RTD sensor individually. Similarly, the controller/processing device may control each heating element individually. In addition, or alternatively, the controller/processing device 105 may control a plurality of the heating elements 230 with a single control signal. Similarly, the controller/processing device 105 may control the RF electrodes individually or collectively.

In various embodiments, various components such as the RTD sensors, heating elements, channel, and/or RF electrodes integrated within the shaft may be controlled separate from the heating element, channel, RTD sensors and/or RF electrodes integrated within the heater plate.

In various embodiments, the RF electrode 220, the heating element 230, and the RTD sensors 225 may be applied to each layer 215 separately by screen printing or other suitable method. The layers 215 may then be laminated together using a bonding method, such as diffusion bonding, static pressing, or any other suitable method, to form the laminated heater plate 125.

Electrical connections to/from the RF electrode 220, the heating element 230, and RTD sensors 225 may be routed throughout the layers 215, through the hollow area of the shaft 130 and to the controller 105.

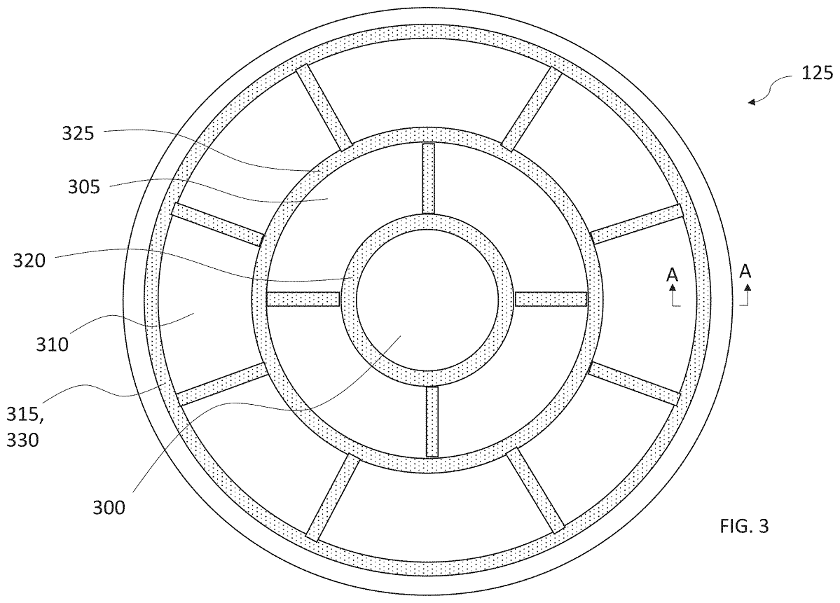

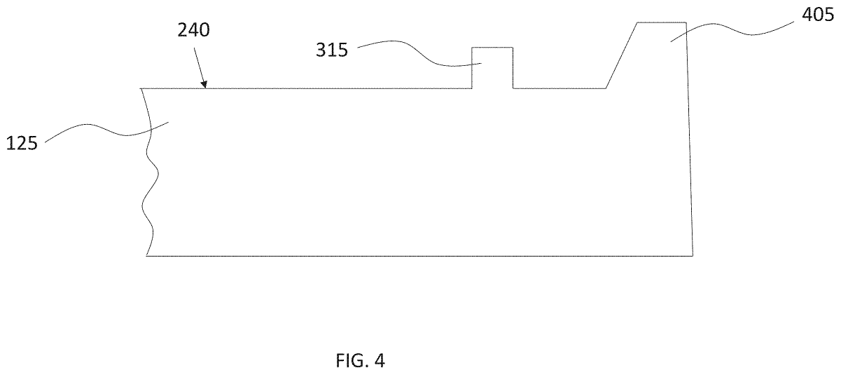

In various embodiments, and referring to FIGS. 3 and 4, the top surface 240 of the laminate heater plate 125 may comprise a minimum contact area 315 comprising a raised bump or ridge pattern (as illustrated in FIG. 3) extending or otherwise protruding from the top surface 240, for which the wafer 135 rests directly on. The minimum contact area 315 may comprise any desired shape or pattern.

In addition, the laminate heater plate 125 may further comprise a raised edge 405 around the perimeter of the heater plate 125 to create a pocket for the wafer 135 to settle into. The raised edge 405 may prevent the wafer 135 from moving side-to-side and enable the wafer 135 to maintain a desired centered position on the heater plate 125.

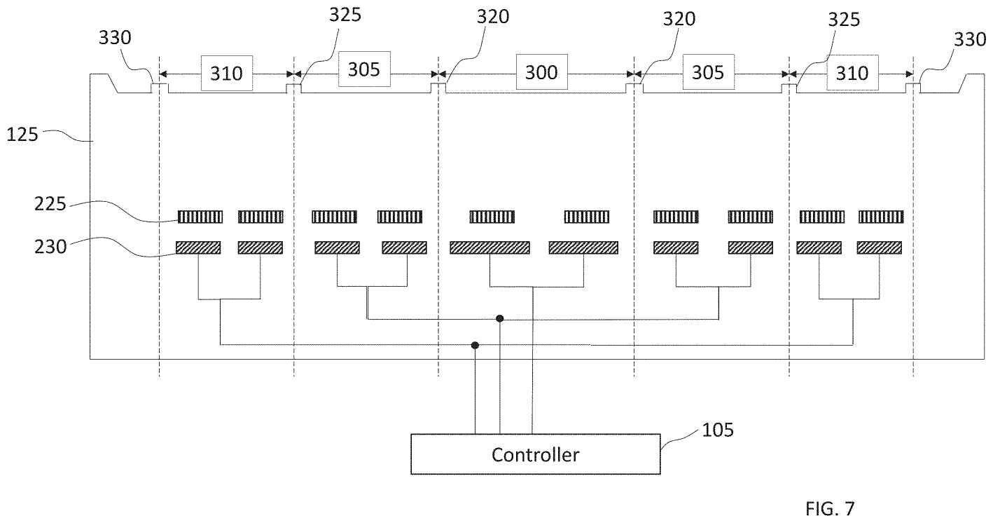

In an exemplary embodiment, and referring to FIGS. 3 and 7, the minimum contact area may comprise a first ring 320, a second ring 325, and a third ring 330. The first, second, and third rings 320, 325, 330 may be concentric with a center point of the heater plate 125 and concentric with each other. The first ring 320 may have a first diameter and be located a first distance from the center point, the second ring 325 may have a second diameter and be located a second distance from the center point, and the third ring 330 may have a third diameter and be located a third distance from the center point. The second distance may be greater than the first distance and less than the third distance. In an exemplary embodiment, the first ring 320 defines a first temperature zone 300, the second ring 325 defines a second temperature zone 305, and the third ring defines a third temperature zone 310. In particular, the first temperature zone 300 is the area within the first ring 320, the second temperature zone 305 is the area between the first ring 320 and the second ring 325, and the third temperature zone 310 is the area between the second ring 325 and the third ring 330. In other embodiments, however, temperature zones may be defined by other structures, such as the heating elements 230.

In various embodiments, the temperature zones may be defined according to the electrical connections and locations of the heating elements 230. For example, a first set of heating elements may be electrically connected and operated together, while a second set of heating elements may be electrically connected and operated together, while a third set of heating elements may be electrically connected and operated together. In this case, the first, second, and third sets of heating elements may be electrically isolated from each other. For example, each set may be electrically connected to a single controller 105, but the controller 105 may generate a first control signal and transmit the first control signal to the first set of heating elements. In addition, the controller 105 may generate a second control signal and transmit the second control signal to the second set of heating elements. In addition, the controller 105 may generate a third control signal and transmit the second control signal to the third set of heating elements. In an exemplary embodiment, the heating elements 230 located within the first temperature zone 300 may all receive the first control signal, the heating elements 230 located within the second temperature zone 305 may receive the second control signal, and the heating elements 230 located within the third temperature zone 310 may receive the third control signal. Each control signal may correspond to a particular desired temperature.

In various embodiments, the controller 105 may generate the control signals based on signals and/or data from the RTD sensor 225 and independently control sets of heating elements based on signals from the RTD sensor 225. For example, the signals from the RTD sensors that are adjacent to a particular set of heating elements 230 may be used to control those particular heating elements 230. In particular, and referring to FIG. 7, signals from the RTD sensors 225 located in the first temperature zone 300 and adjacent to the first set of heating elements may be used to the control the first set of heating elements. Similarly, signals from the RTD sensors 225 located in the second temperature zone 305 and adjacent to the second set of heating elements may be used to the control the second set of heating elements. Similarly, signals from the RTD sensors 225 located in the third temperature zone 310 and adjacent to the third set of heating elements may be used to the control the third set of heating elements.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. A substrate support assembly, comprising:
a laminate heater plate comprising:
a plurality of layers comprising:
a first layer comprising an RF electrode;
a second layer comprising a first resistance temperature detector (RTD); and
a third layer comprising a heating element;
wherein the first, second, and third layers are arranged horizontally and stacked; and
a first channel extending vertically through the plurality of layers;
a shaft coupled to the laminate heater plate and comprising:
a hollow center defined by a sidewall; and
a second channel disposed within the sidewall and fluidly connected to the first channel.

2. The substrate support assembly according to claim 1, wherein each layer from the plurality of layers is formed from a ceramic material comprising aluminum nitride (AlN), aluminum oxide (Al₂O₃), or dialuminium magnesium tetraoxide (Al₂MgO₄).

3. The substrate support assembly according to claim 1, wherein the second layer comprises a first plurality of RTDs forming concentric circles.

4. The substrate support assembly according to claim 1, wherein the third layer comprises a plurality of heating elements comprising a first heating element, a second heating element, and a third heating element.

5. The substrate support assembly according to claim 4, wherein the first heating element is disposed a first distance from a center point of the laminate heater plate, the second heating element is disposed a second distance from the center point of the laminate heater plate, and the third heating element is disposed a third distance from the center point of the laminate heater plate, wherein the second distance is greater than the first distance, and the third distance is greater than the second distance.

6. The substrate support assembly according to claim 5, wherein the first, second, and third heating elements are electrically isolated from each other.

7. The substrate support assembly according to claim 1, wherein the second layer is disposed between the first layer and the third layer.

8. The substrate support assembly according to claim 7, further comprising a fourth layer comprising a second plurality of RTDs.

9. The substrate support assembly according to claim 8, wherein the fourth layer is disposed between the second layer and the third layer.

10. A laminate heater plate comprising:
a plurality of layers comprising:
a first layer comprising an outward facing, top surface;
a second layer comprising an electrode;
a third layer comprising a first plurality of resistance temperature detector (RTD);
a fourth layer comprising a second plurality of RTDs; and
a fifth layer comprising a plurality of heating elements, the plurality of heating elements comprising a first set of heating elements disposed within a first zone, a second set of heating elements disposed within a second zone, and a third set of heating elements disposed within a third zone, wherein the first, second, and third zones are concentric with a center point of the heater plate;
wherein the first, second, third, fourth and fifth layers are arranged horizontally and stacked and in sequence.

11. The laminate heater plate according to claim 10, further comprising a contact area support protruding from the top surface.

12. The laminate heater plate according to claim 10, further comprising a first channel extending vertically from the top surface through at least the second layer.

13. The laminate heater plate according to claim 10, wherein the first set of heating elements, the second set of heating elements, and the third set of heating elements are electrically isolated from each other.

14. The laminate heater plate according to claim 10, further comprising a sixth layer interposed between the second layer and the fifth layer.

15. The laminate heater plate according to claim 14, further comprising a second channel in fluid communication with the first channel and extending horizontally through the sixth layer.

16. The laminate heater plate according to claim 10, wherein:
the second layer further comprises a first ceramic material comprising one of aluminum nitride (AlN), aluminum oxide (Al₂O₃), or dialuminium magnesium tetraoxide (Al₂MgO₄);
the third layer further comprises a second ceramic material that is different from the first ceramic material, the second ceramic material comprising one of aluminum nitride (AlN), aluminum oxide (Al₂O₃), or dialuminium magnesium tetraoxide (Al₂MgO₄) and
the fifth layer further comprises a third ceramic material that is different from the first and second ceramic materials, the third ceramic material comprising one of aluminum nitride (AlN), aluminum oxide (Al₂O₃), or dialuminium magnesium tetraoxide (Al₂MgO₄).

17. The laminate heater plate according to claim 10, wherein each layer from the plurality of layers further comprises a same ceramic material comprising one of aluminum nitride (AlN), aluminum oxide (Al₂O₃), or dialuminium magnesium tetraoxide (Al₂MgO₄).

18. A substrate support assembly, comprising:
a laminate heater plate, comprising:
a plurality of layers formed from a ceramic material, the plurality of layers comprising:
a first layer comprising an outward facing, top surface;
a second layer comprising an electrode;
a third layer comprising a first plurality of resistance temperature detector (RTD);
a fourth layer comprising a second plurality of RTDs; and
a fifth layer comprising a plurality of heating elements, the plurality of heating elements comprising a first set of heating elements, a second set of heating elements, and a third set of heating elements;
a first channel extending vertically from the top surface and through at least one layer from the plurality of layers; and
a second channel extending horizontally through a sixth layer;
a shaft coupled to the laminate heater plate and comprising:
a hollow center defined by a sidewall; and
a third channel disposed within the sidewall.

19. The substrate support assembly according to claim 18, wherein the ceramic material comprises at least one of ceramic material comprising one of aluminum nitride (AlN), aluminum oxide (Al₂O₃), and dialuminium magnesium tetraoxide (Al₂MgO₄).

20. The substrate support assembly according to claim 18, wherein the first set of heating elements is arranged within a first zone, the second set of heating elements is arranged in a second zone, and the third set of heating elements is arranged in a third zone, wherein the first, second, and third zones are concentric with a center point of the laminate heater plate, and wherein each set of heating elements is electrically isolated from the other sets of heating elements.
